(19) United States
(12) Patent Application Publication
(10) Pub. No.: US 2001/0016394 A1
(43) Pub. Date: Aug. 23, 2001

(54) Manufacturing method of semiconductor device having tantalum oxide film

(76) Inventors: Kenichi Koyanagi, Tokyo (JP); Hirofumi Fujioka, Tokyo (JP)

Correspondence Address: SUGHRUE, MION, ZINN, MACPEAK & SEAS, 2100 Pennsylvania Avenue, N.W., Washington, DC, 20037, US

(21) Appl. No.: 09/789,825

(22) Filed: Feb. 22, 2001

(30) Foreign Application Priority Data
Feb. 23, 2000 (JP) 046140/2000

(51) Int. Cl. H01L 21/20

(52) U.S. Cl. 438/396

(57) ABSTRACT

A silicon nitride film is formed on a lower electrode by using remote plasma nitriding processing for performing thermal nitriding within the atmosphere of a nitrogen radical in which nitrogen is decomposed by plasma. After a Ta₂O₅ film is formed on the silicon nitride film, the Ta₂O₅ film is oxidized/crystallized by using remote plasma oxdizing processing for performing thermal oxidation within the atmosphere of an oxygen radical in which oxygen is decomposed by plasma.

### BACKGROUND OF THE INVENTION

1. Field of the Invention

The present invention relates to a method of manufacturing a semiconductor device, and particularly, to a method of manufacturing a semiconductor device having an insulating film including a tantalum oxide film as a metallic oxide.

2. Description of the Related Art

A capacitor element of a structure having an insulating film nipped between two electrodes is formed in an interior of a semiconductor device, particularly, a memory device of a DRAM, etc. so as to store information. In the recent semiconductor device, as the semiconductor device is highly integrated, the capacitor elements, which are formed and incorporated therein themselves are also highly integrated and finely constructed. Therefore, various measures for securing required capacity are taken.

For example, when polysilicon is used in a lower electrode of the capacitor element, a technique is attempted, for increasing a surface area by forming fine irregularities on a surface of the lower electrode. Specifically, a method of forming spherical or hemispherical grains called HSG (Hemispherical Grained Polysilicon) on the surface of the lower electrode is proposed.

Further, a method for increasing capacity by using a high dielectric constant material in the insulating film is also proposed. A tantalum oxide (Ta₂O₅) film is known as such a high dielectric constant material.

We are thinking forming the structure, in which such methods are combined to increase the capacitor of the capacitor element by a process shown in FIGS. 9A to 9D.

FIGS. 9A to 9D are a cross-sectional view showing a manufacturing process of the capacitor element arranged in the semiconductor device of related art. FIGS. 9A to 9D omit a process for forming a transistor and a wiring process, since these processes do not relate to features of the present invention. FIG. 9D shows a situation in which the HSG in the insulating film is omitted to simplify the drawing. However, the real insulating film has a structure as shown in FIG. 9C.

In FIG. 9A, an opening hole 103 connected to a diffusion layer 102 as a drain of a transistor is first formed in an interlayer insulating film 101 formed on a silicon (Si) substrate 100 by using a photolithography technique. Then, a polysilicon film (dose amount: 1×10²⁰/cm³) doped with phosphorus (P) is formed as a lower electrode so as to bury the opening hole 103. Further, the polysilicon is patterned in a desirable shape by using the photolithography technique so that the lower electrode 104 is formed.

Subsequently, while silane (SiH₄) is irradiated, anneal processing (550° C., 20 min) is performed so that a core of the HSG is formed on the lower electrode 104. Further, the grain is grown around the core by performing the anneal processing (550° C., 20 min) in a vacuum. Thus, the HSG 105 is formed on the lower electrode 104 (FIG. 9B).

Next, a silicon nitride film 106 having about 15 angstroms in thickness is formed on the surface of the HSG 105 by RTN (Rapid Thermal Nitrogen: 800° C., 60 seconds, NH₃; 5SLM) processing for performing thermal nitriding in a short period of time in an atmosphere including nitrogen. A Ta₂O₅ film 107 having about 100 angstroms in thickness is formed on this silicon nitride film 106 by a CVD method (FIG. 9C).

Subsequently, the Ta₂O₅ film 107 is oxidized and also crystallized by performing RTO (Rapid Thermal Oxygen: 800° C., 60 seconds, O₂; 5SLM) processing for performing thermal oxidation in a short period of time in an atmosphere including oxygen (O₂) so that an insulating film 108 is formed. After the Ta₂O₅ film 107 is grown on the HSG 105, there is also a case in which the Ta₂O₅ film 107 is oxidized by performing UV (Ultra-Violet) anneal processing (500° C., five minutes) in an ozone (O₃) atmosphere.

Thereafter, to form a capacitor element, a titanium nitride (TiN) film 109 having about 100 angstroms in thickness is grown on the above insulating film 108 by the CVD method to restrain a reaction of the Ta₂O₅ film 107 and the polysilicon. A polysilicon film (dose amount: 1×10²⁰/cm³) doped with phosphorus is grown as an upper electrode on this titanium nitride film 109. Finally, phosphorus is activated by performing RTA (Rapid Thermal Anneal: e.g., 700° C., 60 seconds) processing in a nitrogen (N₂) atmosphere. Thus, the upper electrode 110 is patterned in a desirable shape0 by using the photolithography technique (FIG. 9D).

However, a problem exists in that oxygen loss is large in the Ta₂O₅ film formed in the above manufacturing method so that leak electric current is large, and performance of the insulating film of the capacitor element is low.

It is sufficient to perform RTO processing at a higher temperature to reduce the leak electric current. However, the formation of a system on chip (SOC) having a logic device and a memory device mixed with each other is advanced in the recent semiconductor device. Accordingly, there occurs a problem in that the transistor of the logic device is not able to bear thermal processing at a high temperature.

High performance such as a high speed operation is required in the transistor of the logic device. Therefore, boron (B) is injected into a gate electrode (polysilicon) of a p-channel transistor, and phosphorus (P) is injected into a gate electrode (polysilicon) of an n-channel transistor, and the kinds of impurities of the channels and the gate electrodes are set to be in conformity with each other. Thus, a depletion area is formed just below a gate oxide film, and a reduction in ON electric current and a reduction in controllability due to deepening of the channel are prevented.

The capacitor element is normally formed after the transistor is formed. Therefore, when the capacitor element is heated to a high temperature in its forming process, boron (B) in the gate electrode of the p-channel transistor formed in the logic device is diffused within the gate, and is further diffused into the channel through the gate oxide film. Therefore, there occurs a problem in that a threshold voltage Vt of the transistor changes.

The oxygen loss of the Ta₂O₅ film is a phenomenon that occurs due to shortage of oxygen upon the tantalum oxide is crystallized. This oxygen loss becomes a path of the leak electric current. A method of performing the above UV anneal processing (hereinafter called UV/O₃ anneal processing) in the ozone (O₃) atmosphere to supply the insufficient oxygen, is known.

In the UV/O₃ anneal processing, the life time of ozone is extremely shortened at a high temperature. Therefore, the UV/O₃ anneal processing can be used only up to a temperature of about 600° C. Since the Ta₂O₅ film is crystallized at a temperature equal to or higher than about 650° C., it is difficult to oxidize/crystallize the Ta₂O₅ film by only the UV/O₃ anneal processing. Therefore, it is necessary to crystallize the Ta₂O₅ film by performing RTO processing after the UV/O₃ anneal processing.

However, even in this case, it is impossible to sufficiently supply the insufficient oxygen unless temperature in RTO processing is increased to a certain extent (about 800° C.) Therefore, a problem due to the above crystallization is inevitably caused.

As mentioned above, a silicon nitride film (Si₃N₄) is formed on the HSG (or the lower electrode) before the Ta₂O₅ film is formed. This silicon nitride film is formed to prevent the polysilicon on the surface of the lower electrode from being oxidized to form a silicon oxide film due to a high temperature applied in an oxidation/crystallization process of the Ta₂O₅ film, and from relative dielectric constant of the insulating film being reduced. However, the silicon nitride film is also oxidized if the temperature is high, which is applied in the oxidation/crystallization process of the tantalum oxide film. Therefore, an interface layer in an amorphous state of Si, N and O mixed with each other is formed on the lower electrode. Thus, the relative dielectric constant of the entire insulating film including the Ta₂O₅ film is reduced with the result that the capacitor of the capacitor element is reduced.

In the structure of a general purpose DRAM, a memory cell portion for storing information has only an n-channel transistor, and a peripheral circuit constructed by a decoder, a control circuit, etc. has a p-channel transistor and an n-channel transistor, respectively. High performance as in the above logic device is not required in the transistors for the peripheral circuit. Therefore, similar to the gate electrode of the n-channel transistor, phosphorus (P) is injected to the gate electrode (polysilicon) of the p-channel transistor of the peripheral circuit, so that the manufacturing process is shortened.

Accordingly, the problem of changing the threshold voltage Vth by diffusing boron into the channels of the transistor does not occur. Therefore, the oxygen loss of the Ta₂O₅ film is reduced by performing RTO processing at a high temperature with the result that the leak electric current can be reduced. However, when the Ta₂O₅ film is heated to a high temperature, the relative dielectric constant of the insulating film is reduced by forming the above interface layer with the result that the capacitor of the capacitor element is reduced.

### SUMMARY OF THE INVENTION

An object of the present invention is to provide a method of manufacturing a semiconductor device capable of forming an insulating film including a tantalum oxide film in temperature processing at a relatively low temperature at which no performance of a transistor for a logic device is influenced.

Further, another object of the present invention is to provide a method of manufacturing a semiconductor device for forming a capacitor element having an insulating film including tantalum oxide capable of reducing a leak electric current and increase capacity.

A method of manufacturing a semiconductor device of the present invention, comprises:

forming a silicon nitride film on a lower electrode of a capacitor; forming a tantalum oxide film on the silicon nitride film; and oxidizing and crystallizing the tantalum oxide film; wherein one of forming the silicon nitride film and oxidizing and crystallizing the tantalum oxide film is performed by using remote plasma.

A method of forming a semiconductor device of the present invention, comprising:

forming a film on a semiconductor substrate; and annealing the film while exposing the film to one of an oxygen radical and a nitrogen radical without essentially exposing the film to plasma to form one of an oxide film and a nitride film.

A method of forming a semiconductor device of the present invention, comprising:

forming on a semiconductor substrate an insulating film having a through hole to expose a portion of the semiconductor substrate;

forming a lower electrode on the portion through the through hole;

forming a plurality of hemispherical grains on the lower electrode; nitriding surfaces of the lower electrode and the hemispherical grains by using remote plasma method, to form a nitride film on the surfaces of the lower electrode and the hemispherical grains;

forming the Ta₂O₅ film on the nitride film;

oxidizing and crystallizing the Ta₂O₅ film by using remote plasma method;

forming a metal nitride film on the crystallized Ta₂O₅ film; and

forming an upper electrode on the metal nitride film.

Note that any of the manufacturing methods described above may have a process for forming HSG on the lower electrode, and the capacitor element is desirably used to store information of a DRAM.

In the method of manufacturing the semiconductor device described above, the silicon nitride film with a strong oxidation resisting property can be obtained by using the remote plasma nitriding processing. Therefore, a reduction in the relative dielectric constant of an insulating film due to the formation of an interface layer in the oxidation and the crystallization processes of the tantalum oxide film is restrained.

The insulating film of preferable quality may also be obtained even in thermal processing at a low temperature by oxidizing and crystallizing the tantalum oxide film using the remote plasma oxidation processing. Further, the insulating film with more preferable quality can be obtained by performing the thermal processing at a high temperature.

### BRIEF DESCRIPTION OF THE DRAWINGS

The above and other objects, features and advantages of the present invention will become more apparent from the following detailed description when taken in conjunction with the accompanying drawings wherein:

FIG. 1 is a graph showing a relationship of temperature in RTN or RPN processing and a thickness of a silicon nitride film formed on a silicon substrate.

FIG. 2 is a graph showing an increasing amount of the film thickness in a case where the silicon nitride film is thermally oxidized in a constant condition after the silicon nitride film is formed by using RTN or RPN processing.

FIG. 3 is a graph showing a relationship of the temperature in RPO processing and an SiO₂ reduced film thickness of a tantalum oxide film formed on the silicon substrate.

FIG. 4 is a graph showing a relationship of the temperature in RPO processing and a leak electric current density of the tantalum oxide film formed at this temperature.

FIG. 5 is a schematic view showing an outline structure of a remote plasma chamber for realizing the method of manufacturing a semiconductor device according to the present invention.

FIG. 6 is a typical view showing the schematic construction of a manufacturing device of the semiconductor device including the remote plasma chamber shown in FIG. 5.

FIG. 7 is a graph showing the relationship of the SiO₂ reduced film thickness with respect to a forming condition of the tantalum oxide film formed by the method of manufacturing the semiconductor device according to the present invention.

FIG. 8 is a graph showing the relationship of the leak electric current density with respect to the forming condition of the tantalum oxide film formed by the method of manufacturing the semiconductor device according to the present invention.

FIGS. 9A to 9D are process views showing a manufacturing process of a capacitor element arranged in a conventional semiconductor device.

### DETAILED DESCRIPTION OF THE PREFERRED EMBODIMENTS

In the method of manufacturing a semiconductor device according to the present invention, a silicon nitride film is formed on a lower electrode by using remote plasma nitrogen (RPN) processing in which nitrogen is thermally nitrided in the atmosphere of a nitrogen radical decomposed by plasma. Further, similar to the related case, a Ta₂O₅film is oxidized/crystallized by using RTO processing.

Alternatively, similar to the related case, the silicon nitride film is formed by using RTN processing, and the Ta₂O₅ film is oxidized/crystallized by using remote plasma oxygen (RPO) processing in which oxygen is thermally oxidized in the atmosphere of an oxygen radical decomposed by plasma.

Further, the silicon nitride film is formed on the lower electrode by using RPN processing, and the Ta₂O₅ film is oxidized/crystallized by using RPO processing.

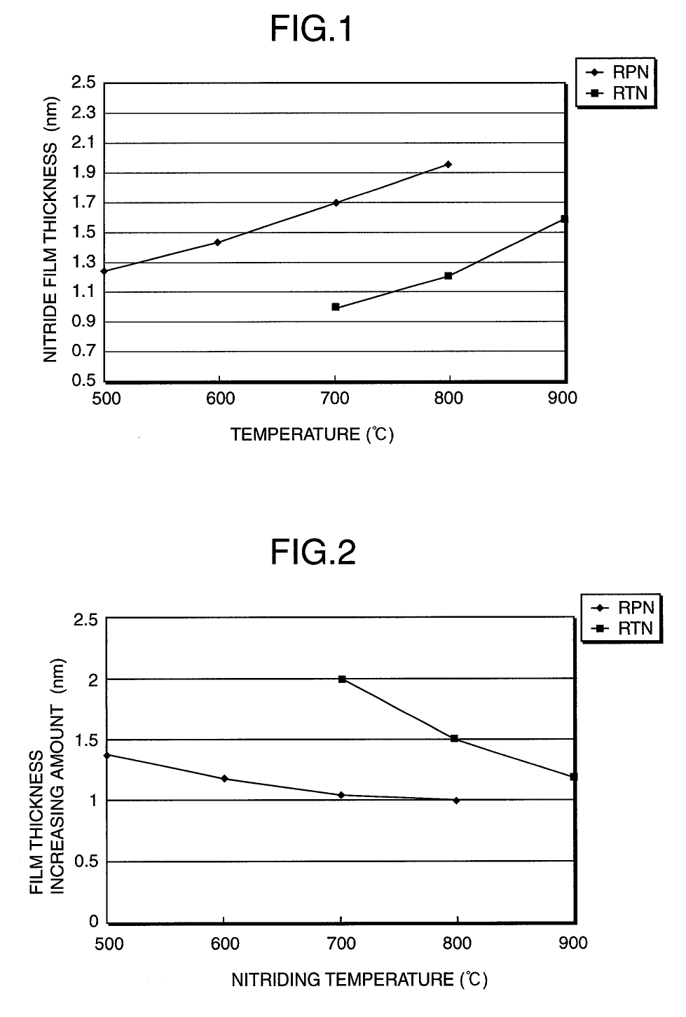

Effects obtained by using RPN processing and RPO processing will first be explained by referring to FIGS. 1 to 4.

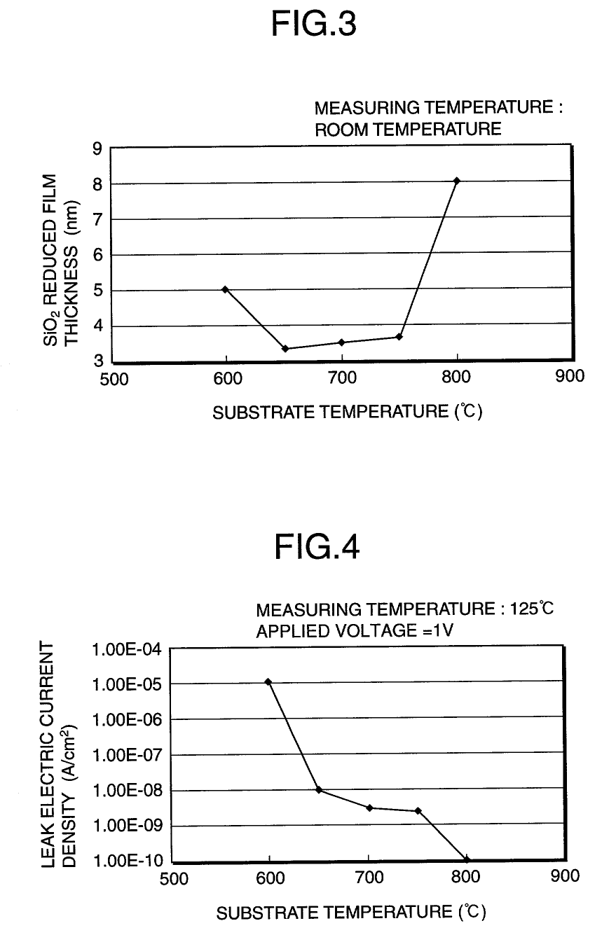

FIG. 1 is a graph showing a relation of temperature in RTN or RPN processing and a thickness of the silicon nitride film formed on a silicon substrate. FIG. 2 is a graph showing an increasing amount of the film thickness when the silicon nitride film is thermally oxidized in a constant condition after the silicon nitride film is formed by using RTN or RPN processing. FIG. 3 is a graph showing a relation of temperature in RPO processing and an SiO₂ reduced film thickness of a tantalum oxide film formed on the silicon substrate. FIG. 4 is a graph showing a relation of a temperature in RPO processing and a leak electric current density of the tantalum oxide film formed at this temperature.

FIG. 2 shows measuring results when the silicon nitride film is oxidized by RPO processing for 60 seconds at 600° C. after the silicon nitride film is formed. FIGS. 3 and 4 show measuring values of a sample capacitor element in which a silicon nitride film having about 15 angstroms in thickness, a Ta₂O₅ film having about 100 angstroms in thickness, a titanium nitride film having about 100 angstroms in thickness are respectively formed on the lower electrode (polysilicon), and an upper electrode (polysilicon) is formed on these films. The silicon nitride film is formed by RTN processing of 800° C. and 60 seconds.

The SiO₂ reduced film thickness shown in FIG. 3 is a value obtained by calculating the thickness of the SiO₂ film providing the same capacity as the measuring value from the capacity measuring value of the above sample capacitor element and an ideal relative dielectric constant of silicon dioxide (SiO₂). Accordingly, FIG. 3 shows that the capacity is increased as the SiO₂ reduced film thickness is reduced.

As shown in FIG. 1, when the silicon nitride film is formed on the silicon substrate and RPN processing is used, the silicon nitride film can be formed from a lower temperature, in comparison with RTN processing. If the thermal processing temperature is the same, a thicker silicon nitride film can be formed in comparison with RTN processing.

As shown in FIG. 2, when the silicon nitride film formed by RPN processing and the silicon nitride film formed by RTN processing are respectively thermally oxidized under the same condition (RPO processing of 600° C. for 60 seconds), an increasing amount of the silicon nitride film formed by the thermal oxidation in RPN processing is reduced in comparison with the silicon nitride film formed in RTN processing. This also holds true even when the nitriding temperature is low.

It is considered that this is because a minute silicon nitride film with reduced defects is formed by RPN processing and this formation prevents permeation of oxygen and restrains the formation of an interface layer. A small increasing amount of the film thickness due to the thermal oxidation shows that an oxidation resisting property of the formed silicon nitride film is strong. Therefore, it is possible to obtain the silicon nitride film having the strong oxidation resisting property in RPN processing in comparison with RTN processing.

As shown in FIG. 2, from the reduction in the increasing amount of the film thickness when the temperature in RPN processing is increased, it should be understood that the oxidation resisting property of the silicon nitride film is strengthened by increasing the processing temperature. Similarly, it should be understood that the oxidation resisting property of the silicon nitride film is also strengthened by increasing the processing temperature in RTN processing.

As shown in FIG. 3, when the Ta₂O₅ film is respectively oxidized/crystallized on the silicon nitride film formed under the same condition (RTN processing of 800° C. for 60 seconds) by changing the temperature in RPO processing, the SiO₂ reduced film thickness is reduced in a range from about 650° C. to 750° C. so that a large capacity value is obtained. It is considered that the relative dielectric constant is reduced and the SiO₂ reduced film thickness is increased since the Ta₂O₅ film is not perfectly crystallized at a temperature equal to or lower than 650° C. It is also considered that the silicon nitride film is oxidized and an interface layer is caused, and the relative dielectric constant of an insulating layer is reduced and the SiO₂ reduced film thickness is increased at a temperature equal to or higher than 750° C. Namely, it should be understood that the Ta₂O₅ film can be oxidized/crystallized at a low temperature in comparison with the conventional case (conventionally 800° C.).

As shown in FIG. 4, the leak electric current density of the Ta₂O₅ film formed at a temperature (equal to or higher than 650° C.) in a crystallizable range is reduced as the temperature is increased. As mentioned above, if the silicon nitride film is formed by using RPN processing, the formation of the interface layer is restrained at a high temperature application time. Therefore, the Ta₂O₅ film can be heated to a high temperature in the oxidation/crystallization process. Accordingly, oxygen loss of the Ta₂O₅ film is reduced and quality of the insulating film is improved so that the leak electric current is reduced. Further, the formation of the interface layer is restrained and the reduction in the relative dielectric constant of the insulating film is restrained so that the capacity of the capacitor element can be increased.

As shown in FIG. 2, the oxidation resisting property of the silicon nitride film is strengthened as the temperature of RPN processing is increased. Accordingly, the Ta₂O₅ film on the silicon nitride film formed by RPN processing at a high temperature may be oxidized/crystallized at a higher temperature. Therefore, the leak electric current can be further reduced.

Accordingly, a selecting width of the thermal processing temperature is widened in comparison with the conventional case if at least one of, the silicon nitride forming process using PPN processing and the oxidation/crystallization process of the Ta₂O₅ film using RPO processing, is performed at a forming time of the capacitor element. For example, when a semiconductor device having a logic device and a memory device mixed with each other is manufactured, the formation of the silicon nitride film and the oxidation/crystallization of the Ta₂O₅ film can be performed at a low temperature at which performance of a transistor for the logic device is not influenced. In a case that a general purpose DRAM, to which high temperature may be applied, is manufactured, the silicon nitride film is formed by RPN processing, and the Ta₂O₅ film is oxidized/crystallized by RTO processing or RPO processing at the high temperature. Thus, the leak electric current density of the capacitor element can be reduced and capacity can be increased.

Oxidation force in RPO processing is stronger than that in the above UV/O₃ anneal processing and RTO processing. Therefore, RPO processing may be also used only in the oxidation process of the Ta₂O₅ film by reducing the processing temperature. In this case, if the Ta₂O₅ film is crystallized by RTO processing or RPO processing at the high temperature, effects similar to those in the above case can be obtained. Further, similar to the conventional case, when the Ta₂O₅ film is oxidized by the UV/O₃ anneal processing after the Ta₂O₅ film is formed on the silicon nitride film, effects similar to those in the above case can be obtained by crystallizing the Ta₂O₅ film using RPO processing.

A concrete manufacturing device of the semiconductor device including the capacitor element will next be explained by using the drawings.

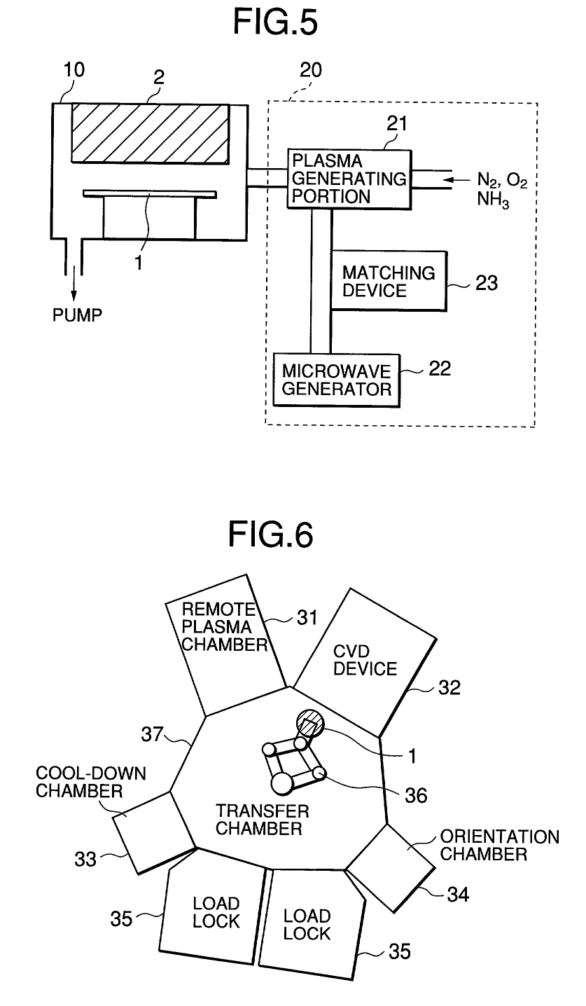

FIG. 5 is a typical view showing the schematic construction of a remote plasma chamber for realizing the method of manufacturing the semiconductor device according to the present invention. FIG. 6 is a typical view showing a schematic construction of the manufacturing device of the semiconductor device including the remote plasma chamber shown in FIG. 5.

In FIG. 5, the remote plasma chamber used in the present invention has a thermal processing chamber 10 for thermally processing a wafer 1, and a remote plasma generator 20 for decomposing an introduced gas (N₂, NH₃, O₂, etc.) by plasma and generating a nitrogen radical and an oxygen radical.

A light source (e.g., a halogen lamp) 2 for heating the wafer 1 is arranged within the thermal processing chamber 10. The gas is introduced through the remote plasma generator 20, and the gas within the chamber 10 is discharged through an unillustrated pump.

The remote plasma generator 20 has a plasma generating portion 21 as a sealed space for generating the plasma, a microwave generator (magnetron, etc.) 22 for giving energy for generating the plasma in the plasma generating portion 21, and a matching device 23 for adjusting the energy of a microwave emitted from the microwave generator 22 so that this energy is maximized in the plasma generating portion 21.

Since the thermal processing chamber 10 and the remote plasma generator 20 for generating the remote plasma are separately constructed, only the nitrogen radical or the oxygen radical is irradiated to the wafer 1 without being exposed to the plasma. If microwave generator 22 is not operated, the gas introduced to the plasma generating portion 21 is guided into the thermal processing chamber 10 as it is. Therefore, the manufacturing device shown in FIG. 5 can be also utilized as a device for performing RTA, RTN and RTO processings.

As shown in FIG. 6, the manufacturing device is constructed to have a remote plasma chamber 31 including the thermal processing chamber 10 and the remote plasma generator 20 shown in FIG. 5, a CVD device 32 for forming a Ta₂O₅ film on the wafer 1, a cool-down chamber 33 for cooling the wafer 1 thermally processed, an orientation chamber 34 for adjusting an orientation of the wafer 1, a load lock 35 for accumulating the wafer 1 waiting for processing/processed, and a transfer chamber 37 including a robot arm 36 for conveying the wafer 1. Accordingly, nitriding processing of a lower electrode surface, formation of the Ta₂O₅ film, and its oxidation/crystallization processing can be performed by one device.

The Si reduced film thickness of the Ta₂O₅ film formed by using the above manufacturing device, and the leak electric current density will next be explained.

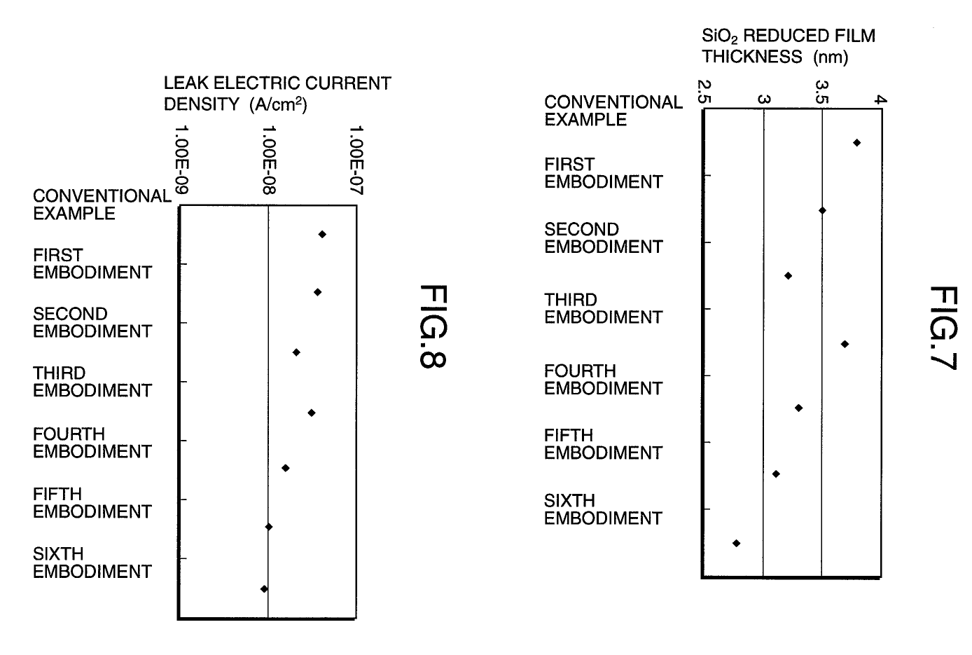

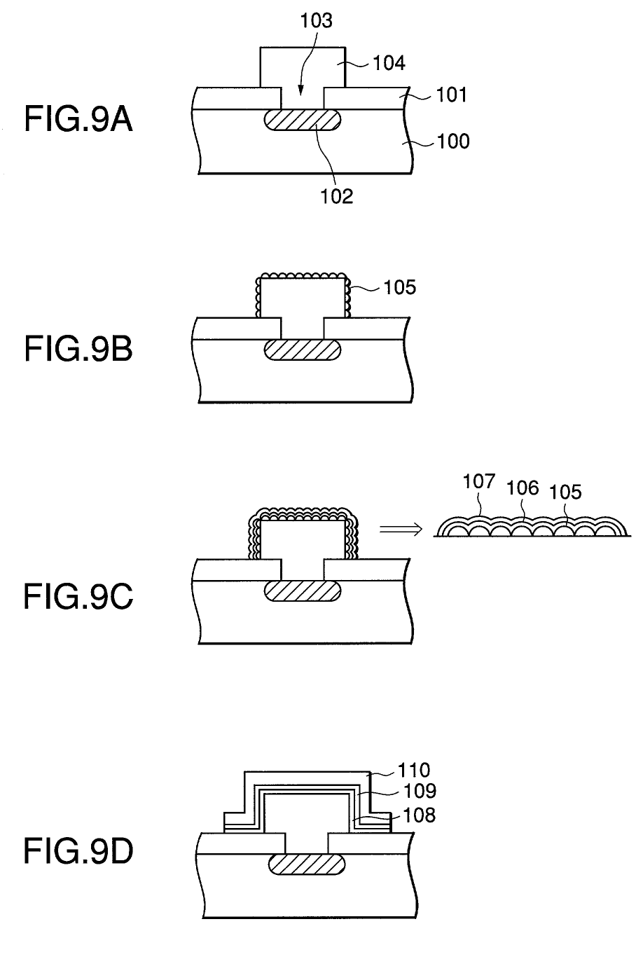

FIG. 7 is a graph showing the relation of the SiO₂ reduced film thickness with respect to a forming condition of the tantalum oxide film formed by the method of manufacturing the semiconductor device according to the present invention. FIG. 8 is a graph showing the relation of the leak electric current density with respect to the forming condition of the tantalum oxide film formed by the method of manufacturing the semiconductor device according to the present invention.

FIGS. 7 and 8 show values obtained by measuring the characteristics of a sample capacitor element in which a silicon nitride film having about 15 angstroms in thickness, a Ta₂O₅ film having about 100 angstroms in thickness, and a titanium nitride film having about 100 angstroms in thickness are respectively formed on a lower electrode (polysilicon), and an upper electrode (polysilicon) is formed on these films. The SiO₂ reduced film thickness shown in FIG. 7 is a value obtained by calculating the thickness of the SiO₂ film providing the same capacity as the measuring value, from the capacity measuring value of the above sample capacitor element and an ideal relative dielectric constant of silicon dioxide (SiO₂) . Further, the conventional examples of FIGS. 7 and 8 show values obtained when the silicon nitride film is formed by RTN processing of 800° C. for 60 seconds, and when the Ta₂O₅ film is oxidized/crystallized by RTO processing of 800° C. for 60 seconds. The SiO₂ reduced film thickness of FIG. 7 is a measuring value obtained when there is no HSG on the lower electrode. The leak electric current density of FIG. 8 is a measuring value obtained when there is the HSG on the lower electrode.

The silicon nitride film and the Ta₂O₅ film formed on the lower electrode are set to be thermally processed in the following conditions of six kinds in a first embodiment to a sixth embodiment.

First embodiment: RPN; 650° C. for 60 seconds, RTO; 800° C. for 60 seconds

Second embodiment: RPN; 800° C. for 60 seconds, RTO; 900° C. for 60 seconds

Third embodiment: RTN; 800° C. for 60 seconds, RPO; 680° C. for 60 seconds

Fourth embodiment: RTN; 1000° C. for 60 seconds, RPO; 800° C. for 60 seconds

Fifth embodiment: RPN; 650° C. for 60 seconds, RPO; 680° C. for 60 seconds

Sixth embodiment: RPN; 800° C. for 60 seconds, RPO; 800° C. for 60 seconds

In the first embodiment, the silicon nitride film is formed by using RPN processing at a low temperature, and the Ta₂O₅ film is oxidized/crystallized by using RTO processing at a high temperature. The oxidation resisting property of the silicon nitride film formed by RPN processing is improved, and the formation of an interface layer is restrained at a crystallizing time of the Ta₂O₅ film, and the reduction in the relative dielectric constant of the insulating film is restrained. Therefore, as shown in FIG. 7, the capacity of the capacitor element is increased and the SiO₂ reduced film thickness is reduced in comparison with the conventional example.

In the second embodiment, the silicon nitride film is formed by using RPN processing at a high temperature so that the Ta₂O₅ film is oxidized/crystallized by RTO processing at a higher temperature than the first embodiment. Since RPN processing at a high temperature is performed, the oxidation resisting property of the silicon nitride film is improved, and RTO processing can be performed at a high temperature. Therefore, the reduction in the relative dielectric constant of the insulating film is restrained in comparison with the first embodiment, and the SiO₂reduced film thickness is further reduced as shown in FIG. 7. Further, since RPN processing is performed at a high temperature, the quality of the Ta₂O₅ film is improved and the leak electric current is reduced in comparison with the first embodiment as shown in FIG. 8.

In the third embodiment, the silicon nitride film is formed by RTN processing at a high temperature, and the Ta₂O₅ film is oxidized/crystallized by RPO processing at low temperature. The Ta₂O₅ film may be oxidized/crystallized by using RPO processing at a lower temperature than the conventional case.

As shown in FIG. 7, the SiO₂ reduced film thickness is also reduced in RPO processing at a low temperature in comparison with the conventional example, so that an increase in capacity is recognized as an effect. Further, the leak electric current is also reduced as shown in FIG. 8.

In the fourth embodiment, the silicon nitride film is formed by using RTN processing at a higher temperature than the third embodiment, and the Ta₂O₅ film is oxidized/crystallized by using RPO processing at a higher temperature than the third embodiment. Since RTN processing is performed at a higher temperature than the third embodiment, the oxidation resisting property of the silicon nitride film is improved, and the formation of an interface layer is restrained, and the reduction in the relative dielectric constant is further restrained. Therefore, as shown in FIG. 7, the SiO₂ reduced film thickness is reduced in comparison with the third embodiment. Further, since quality of the Ta₂O₅ film is improved by performing RPO processing at a higher temperature, the leak electric current is reduced in comparison with the third embodiment as shown in FIG. 8.

The fifth embodiment is an example where the silicon nitride film is formed by using RPN processing at a low temperature, and the Ta₂O₅ film is oxidized/crystallized by using RPO processing at a low temperature. Since the silicon nitride film is formed by using RPN processing at a low temperature and the Ta₂O₅ film is oxidized/crystallized by using RPO processing at a low temperature, the SiO₂ reduced film thickness is reduced and the leak electric current is reduced in comparison with the above first to fourth embodiments as shown in FIGS. 7 and 8. Such a method using RPN processing and RPO processing at a low temperature is preferably used in the manufacture of the semiconductor device in which the logic device is mixed.

The sixth embodiment is an example where the silicon nitride film is formed by RPN processing at a high temperature, and the Ta₂O₅ film is oxidized/crystallized by RPO processing at a high temperature. Since the silicon nitride film is formed by using RPN processing at a high temperature and the Ta₂O₅ film is oxidized/crystallized by using RPO processing at a high temperature, the SiO₂ reduced film thickness is further reduced and the leak electric current is reduced in comparison with the fifth embodiment as shown in FIGS. 7 and 8. Such a method using RPN processing and RPO processing at a high temperature is preferably used in the manufacture of a general purpose DRAM, etc.

In the above explanation, a case where no HSG is formed on the lower electrode is given as an example. However, it goes without saying that the HSG may be also formed on the lower electrode to further increase the capacity of the capacitor element.

Since the present invention is constructed as explained above, the present invention has the following effects.

The silicon nitride film having a strong oxidation resisting property can be obtained by using the remote plasma nitriding processing. Therefore, the reduction in the relative dielectric constant of an insulating film due to the formation of an interface layer in oxidation and crystallization processes of the tantalum oxide film is restrained, and capacity of the capacitor element can be increased.

The insulating film of preferable quality is also obtained even in thermal processing at a low temperature by oxidizing and crystallizing the tantalum oxide film using the remote plasma oxidation processing. Further, the insulating film of more preferable quality can be obtained by performing the thermal processing at a high temperature so that the leak electric current of the capacitor element can be reduced.

Further, the capacity of the capacitor element may be increased and the leak electric current can also be reduced by forming the silicon nitride film on the lower electrode using the remote plasma nitriding processing, and oxidizing and by crystallizing the tantalum oxide film using the remote plasma oxidation processing.

What is claimed is:

1. A method of manufacturing a semiconductor device, comprising:
forming a silicon nitride film on a lower electrode of a capacitor;
forming a tantalum oxide film on said silicon nitride film; and
oxidizing and crystallizing the tantalum oxide film; wherein one of forming said silicon nitride film and oxidizing and crystallizing the tantalum oxide film is performed by using remote plasma.

2. The method as claimed in claim 1, wherein said silicon nitride film is formed by using remote plasma nitriding processing for performing thermal nitriding within the atmosphere of a nitrogen radical in which nitrogen is decomposed by plasma.

3. The method as claimed in claim 1, wherein said tantalum oxide film is oxidized and crystallized by using remote plasma oxidizing processing for performing thermal oxidation within the atmosphere of an oxygen radical in which oxygen is decomposed by plasma.

4. The method as claimed in claim 1, wherein a hemispherical grained polysilicon is formed on said lower electrode before said silicon nitride film is formed.

5. A method of forming a semiconductor device, comprising:
forming a film on a semiconductor substrate; and
annealing said film while exposing said film to one of an oxygen radical and a nitrogen radical without essentially exposing said film to plasma to form one of an oxide film and a nitride film.

6. The method as claimed in claim 5, wherein said oxide film and said nitride film are formed by remote plasma processing.

7. The method as claimed in claim 6, wherein said oxide film is formed at a temperature between 650° C. and 750° C.

8. A method of forming a semiconductor device, comprising:
forming on a semiconductor substrate an insulating film having a through hole to expose a portion of said semiconductor substrate;
forming a lower electrode on said portion through said through hole;
forming a plurality of hemispherical grains on said lower electrode;
nitriding surfaces of said lower electrode and said hemispherical grains by using remote plasma method, to form a nitride film on said surfaces of said lower electrode and said hemispherical grains;
forming the Ta₂O₅ film on said nitride film;
oxidizing and crystallizing said Ta₂O₅ film by using remote plasma method;
forming a metal nitride film on the crystallized Ta₂O₅ film; and
forming an upper electrode on said metal nitride film.
